(19) United States
(12) Patent Application Publication
(10) Pub. No.: US 2026/0367523 A1
(43) Pub. Date: Nov. 19, 2026

(54) SPLASH-PROOFING DEVICE FOR PHOTORESIST STRIPPING PROCESS, PHOTORESIST STRIPPING APPARATUS, AND CHEMICAL SOLUTION DELIVERY DEVICE

(71) Applicant: ACM RESEARCH (SHANGHAI), INC., Shanghai (CN)

(72) Inventors: Zeran Li, Shanghai (CN); Zhenming Chu, Shanghai (CN); Zhaoming Zhong, Shanghai (CN); Xideng He, Shanghai (CN)

(73) Assignee: ACM RESEARCH (SHANGHAI), INC., Shanghai (CN)

(21) Appl. No.: 19/487,392

(22) PCT Filed: May 6, 2024
(86) PCT No.: PCT/CN2024/091134

§ 371 Date: Nov. 24, 2025

(30) Foreign Application Priority Data
May 22, 2023 (CN) 202310575722.9

(51) Int. Cl. G03F 7/42

(52) U.S. Cl. CPC G03F 7/422

(57) ABSTRACT

A splash-proofing device is disposed inside a chamber and includes a blocking assembly, an exhaust assembly, a stage, and a nozzle. The stage is used to support a substrate, and the nozzle is positioned above the stage at a preset height. The blocking assembly includes at least one protection plate disposed at the periphery of the substrate. The exhaust assembly includes an exhaust duct and an exhaust hood that are in communication with each other. The exhaust hood is disposed at the periphery of the nozzle, and an exhaust port of the exhaust hood is disposed above the substrate. The exhaust assembly is used to draw splashed atomized chemical solution out of the chamber. The protection plate forms a barrier that blocks chemical solution splashing, and the exhaust assembly, by suction, draws the atomized chemical solution out of the chamber through the exhaust hood and then the exhaust duct.

### FIELD OF THE INVENTION

The present invention relates to the field of semiconductor device manufacturing, and in particular to a splash-proofing device for a photoresist stripping process, a photoresist stripping apparatus, and a chemical solution delivery device.

### BACKGROUND

During substrate processing, photoresist is employed to form desired patterns on the surface of a substrate. In subsequent processes, the photoresist must be removed. However, due to adhesion between the photoresist and the underlying film layer, conventional stripping methods often fail to achieve complete removal of the photoresist, leaving residues, thereby affecting the yield of the substrate.

To address the problem of photoresist residues, high-pressure stripping processes were later introduced. Nevertheless, such high-pressure stripping processes bring about the problem of chemical solution splashing, wherein the chemical solution splashes into a chamber, adversely affecting subsequent substrate processing.

### SUMMARY

In view of the above problem, the purpose of the present invention is to provide a splash-proofing device for a photoresist stripping process, a photoresist stripping apparatus, and a chemical solution delivery device, effectively preventing chemical solution splashing.

To achieve the above object, the present invention provides the following technical solution:

A splash-proofing device for a photoresist stripping process, disposed in a chamber, comprising a blocking assembly, an exhaust assembly, a stage, and a nozzle;

the stage being used to support a substrate, and the nozzle being disposed above the stage at a preset height;

the blocking assembly including at least one protection plate disposed at the periphery of the substrate for preventing chemical solution sprayed onto the substrate from splashing into the chamber;

the exhaust assembly comprising an exhaust duct and an exhaust hood in communication with each other, the exhaust hood being disposed at the periphery of the nozzle, an exhaust port of the exhaust hood being disposed above the substrate, and the exhaust assembly being used to draw splashed atomized chemical solution out of the chamber.

The present invention also provides a photoresist stripping apparatus, and the photoresist stripping apparatus comprises a first chamber, a filtration unit, and the splash-proofing device. The splash-proofing device is disposed in the first chamber. The top of the first chamber is provided with vent holes, and the vent holes are in communication with the filtration unit for introducing filtered gas.

The present invention further provides a chemical solution delivery device applied on the photoresist stripping apparatus. The chemical solution delivery device comprises a chemical solution supply unit, delivery pipes, and valves. The chemical solution supply unit delivers the chemical solution via the delivery pipes to nozzles in different chambers. For different delivery paths, the numbers of the valves are the same, and the lengths of the delivery pipes are identical.

Compared with the prior art, the present invention provides the following benefits:

The blocking assembly comprises at least one protection plate disposed at the periphery of the substrate. Acting as a protective barrier, the protection plate efficiently prevents the chemical solution sprayed onto the substrate from splashing into the chamber.

Under high pressure, a portion of the chemical solution is prone to atomization. For the chemical solution with a small droplet diameter, further, the exhaust assembly, by suction, draws the atomized chemical solution out of the chamber through the exhaust hood and then the exhaust duct. This effectively prevents chemical solution splashing, keeps the chamber interior clean, and thereby facilitating subsequent substrate processing. In addition, the cleaning frequency of the chamber interior is reduced, improving the efficiency of substrate processing.

### BRIEF DESCRIPTION OF THE DRAWINGS

The features and performances of the present invention are further described via the following embodiments and the accompanying drawings.

FIG. 1 shows a first-perspective schematic structural view of a splash-proofing device according to Embodiment 1 of the present invention.

FIG. 2 shows a second-perspective schematic structural view of the splash-proofing device according to Embodiment 1 of the present invention.

FIG. 3 shows a side view of a protection plate according to Embodiment 1 of the present invention.

FIG. 4 shows a schematic structural view of a horizontal position adjustment unit according to Embodiment 1 of the present invention.

FIG. 5 shows a schematic structural view of a photoresist stripping apparatus according to Embodiment 2 of the present invention.

FIG. 6 shows a schematic structural view of a photoresist stripping apparatus according to another embodiment of the present invention.

FIG. 7 shows a schematic structural view of a chemical solution delivery device according to Embodiment 3 of the present invention.

[Description of reference numerals]: splash-proofing device 1, first chamber 2, second chamber 3, filter 4, chemical solution supply unit 5, delivery pipe 6, valve 7;
blocking assembly 11, exhaust assembly 12, stage 13, nozzle 14, support base 15, horizontal position adjustment unit 16, swing member 17, cleaning unit 18;
protection plate 111, baffle 112, first portion 1111, second portion 1112;
exhaust duct 121, exhaust hood 122;
horizontal guide rail 161, slide block 162, first driving module 163;
fixed rod 171, swing arm 172;
recovery tank 181, flushing unit 182, inlet conduit 1821, spray head 1822;
vent hole 21.

### PREFERRED EMBODIMENTS OF THE INVENTION

To more clearly illustrate the technical solution of the embodiments of the present application, drawings needed in the description of the embodiments will be briefly introduced in the following text. Obviously, the drawings in the following description are only some examples or embodiments of the present application. For those of ordinary skill in the art, the present application can be applied to other similar scenarios according to these drawings without creative efforts. Unless clearly indicated or stated otherwise in the context, the same reference numerals in the drawings indicate the same structure or operation.

As shown in the present application and the claims, unless the context clearly indicates exceptions, words such as “one,” “a/an,” and/or “the” apply to both the singular and plural forms. Generally speaking, the terms “comprise” and “include” only suggest that clearly identified steps and elements are included, and these steps and elements do not constitute an exclusive list. A method or a device may also include other steps or elements.

Unless otherwise specified, the relative arrangement of components and steps, numerical expressions, and numerical values set forth in these embodiments do not limit the scope of the present application. In addition, it should be understood that for the convenience of description, the sizes of various parts shown in the drawings are not drawn according to actual proportional relationships. Technologies, methods, and devices known to those of ordinary skill in the art may not be discussed in detail, but where appropriate, these technologies, methods, and devices should be regarded as a part of the authorized specification. In all examples shown and discussed herein, any specific value should be interpreted as merely exemplary, not as a limitation. Therefore, other examples of the exemplary embodiments may provide different values. It should be noted that similar reference numerals and letters indicate similar items in the following drawings. Therefore, once an item is defined in one drawing, the item does not need to be further discussed in subsequent drawings.

In the description of the present application, it should be understood that direction words such as “front, rear, upper, lower, left, right,” “transverse, vertical, perpendicular, horizontal,” and “top, bottom” usually refer to the directions or positional relationships shown in the drawings. These direction words are only for the convenience of describing the present application and simplifying the description. Unless stated otherwise, these direction words do not indicate or imply that the apparatus or element must provide a specific direction or be constructed and operated in a specific direction, so the direction words cannot be understood as limiting the protection scope of the present application; the direction words “inner, outer” refer to the inner and outer relative to the outline of each component itself.

For the convenience of description, spatial relative terms such as “on,” “above,” “on the surface,” “upper,” and the like can be used here to describe spatial position relationships between one device or feature and other devices or features, as shown in the drawings. It should be understood that the spatial relative terms are intended to include different directions of a device in use or operation, in addition to the directions shown in the drawings. For example, if a device in a drawing is turned over, the device described as “above another device or structure” or “on another device or structure” will then be positioned as “below another device or structure” or “under another device or structure.” Thus, the exemplary term “above” can include both the directions of “above” and “below.” The device can also be positioned in other ways (rotated 90 degrees or in other directions), and the spatial relative descriptions used here can be interpreted accordingly.

In addition, it should be noted that words such as “first” and “second” used to define components are only for the convenience of distinguishing corresponding components. Unless otherwise stated, the above words have no special meaning, so the words cannot be understood as limiting the protection scope of the present application. In addition, although the terms used in the present application are selected from publicly known and used terms, some terms in the specification of the present application may be selected by the applicant according to his or her judgment, and the detailed meanings of the terms are set forth in the relevant part of the description herein. In addition, the present application should be understood through both the actual terms used and the meaning implied by each term.

The technical solution of the present invention will be further described below with reference to the drawings and through specific embodiments.

### Embodiment 1

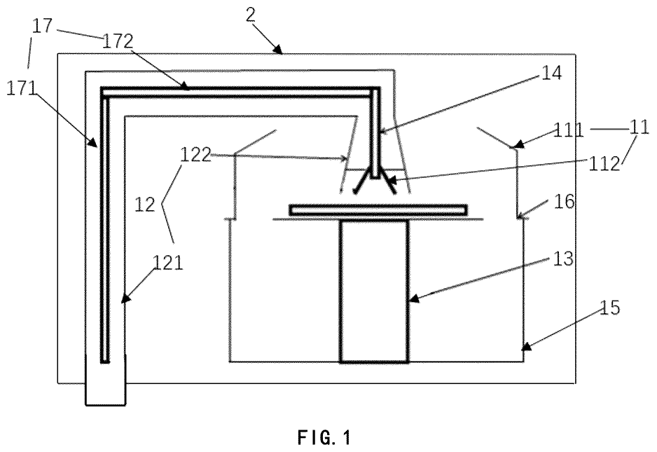

According to FIG. 1, the embodiment of the present application provides a splash-proofing device 1 comprising a blocking assembly 11 disposed in a first chamber 2, an exhaust assembly 12, a stage 13, a nozzle 14, a support base 15, and a horizontal position adjustment unit 16. The stage 13 is used to support a substrate. The nozzle 14 is disposed above the stage 13 at a preset height. The nozzle 14 sprays a chemical solution onto the surface of the substrate to remove photoresist. The support base 15 surrounds the stage 13.

The exhaust assembly 12 comprises an exhaust duct 121 and an exhaust hood 122 in communication with each other. The exhaust hood 122 is disposed at the periphery of the nozzle 14, and the exhaust port of the exhaust hood 122 is disposed above the substrate. The exhaust duct 121 is connected to an external vacuum pump set.

The blocking assembly 11 comprises at least one protection plate 111 and a baffle 112. The protection plate 111 is disposed at the periphery of the substrate. The baffle 112 is tilted at a preset angle on the nozzle 14. Further, when the preset angle is an acute angle, the chemical solution can be effectively blocked.

The baffle 112 serves as the first protective barrier to prevent the chemical solution sprayed onto the substrate from splashing into the first chamber 2. The protection plate 111 serves as the secondary protective barrier to further prevent the chemical solution sprayed onto the substrate from splashing into the first chamber 2. The dual protective barriers can efficiently prevent chemical solution splashing. Additionally, the baffle 112 can also protect the surface of the nozzle 14 from being contaminated by the chemical solution.

The nozzle 14 sprays the chemical solution, and a portion of the chemical solution atomizes into fine droplets under high pressure. For the chemical solution with a small droplet diameter, furthermore, the exhaust assembly 12, by suction, draws the atomized chemical solution out of the first chamber 2 through the exhaust hood 122 and then the exhaust duct 121. The apparatus can effectively prevent chemical solution splashing, keep the interior of the first chamber 2 clean, and thereby facilitate subsequent substrate processing. In addition, the cleaning frequency of the interior of the first chamber 2 is reduced, improving the efficiency of substrate processing.

The horizontal position adjustment unit 16 is disposed on the support base 15. The protection plate 111 is movably mounted on the horizontal position adjustment unit 16. The horizontal position adjustment unit 16 adjusts the position of the protection plate 111 in time based on splashing conditions. The protection plate 111 can be adjustable between an open state and a closed state. If the splashing amplitude of the chemical solution is small and there is also an amount of the chemical solution splashes into the first chamber 2, the horizontal position adjustment unit 16 adjusts the protection plate 111 to converge toward the center position of the substrate.

The splash-proofing device 1 comprises at least two horizontal position adjustment units 16. The blocking assembly 11 comprises at least two protection plates 111. Specifically, as shown in FIG. 1, the splash-proofing device 1 comprises two horizontal position adjustment units 16. The blocking assembly 11 comprises two protection plates 111 symmetrically disposed on both sides of the stage 13. Each protection plate 111 is disposed on a corresponding horizontal position adjustment unit 16. The two protection plates 111 can form a ring to block chemical solution splashing in all directions. Alternatively, the two protection plates 111 may not form a ring but block chemical solution splashing in a specific direction, respectively. The installation positions of the two protection plates 111 can be determined based on the directions of chemical solution splashing.

The number of protection plates 111 is not limited thereto. Preferably, the splash-proofing device 1 comprises four horizontal position adjustment units 16, the blocking assembly 11 comprises four protection plates 111, and the four protection plates 111 are respectively disposed in four cardinal directions around the stage 13 to more effectively block chemical solution splashing. Similarly, the four protection plates 111 can form a ring or not.

Optionally, the protection plates 111 are of a curved-surface structure. Two protection plates 111 are disposed at the periphery of the substrate, and the curved-surface structure is more conducive to blocking chemical solution splashing.

To further improve the cleanliness of the interior of the first chamber 2 and reduce chemical solution splashing, in other embodiments, the blocking assembly 11 comprises two protection plates 111, with the diameter of one protection plate 111 on one side greater than the diameter of the protection plate 111 on the other side. After the two protection plates 111 on both sides are moved to preset positions toward the center position of the substrate, the protection plate with a larger diameter partially envelops the protection plate with a smaller diameter, and the two protection plates are in a closed state.

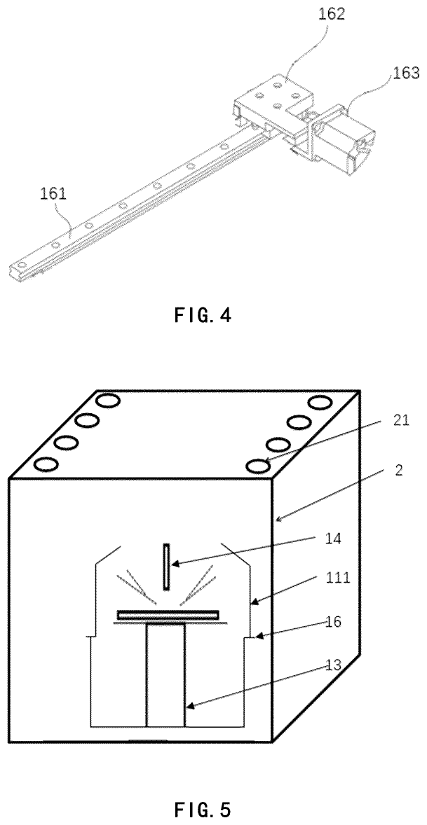

According to FIG. 3, each protection plate 111 comprises a first portion 1111 and a second portion 1112. The second portion 1112 is inclined toward the substrate relative to the first portion 1111. The protection plate 111 can be of a curved-surface structure or a linear structure. Further, according to FIG. 4, the horizontal position adjustment unit 16 comprises a horizontal guide rail 161, a slide block 162, and a first driving module 163. The slide block 162 is slidably mounted on the horizontal guide rail 161. The first portion 1111 is mounted on the slide block 162, and the slide block 162 is disposed at the outlet end of the first driving module 163. The first driving module 163 drives the slide block 162 to slide, thereby moving the protection plate 111 radially relative to the support base 15. Each protection plate 111 can move radially toward or away from the center position of the substrate to be in a closed or open state. Optionally, the protection plate 111 is directly slidably mounted on the horizontal guide rail 161.

In other embodiments, the support base 15 is not configured with a horizontal position adjustment unit 16, and the protection plate 111 is directly mounted on the support base 15. The protection plate 111 is of a hollow frustum structure. Based on the size of the substrate and the conditions of chemical solution splashing, a suitable protection plate 111 is selected in advance.

Exemplarily, the splash-proofing device comprises a control unit connected to the horizontal position adjustment unit 16. The control unit controls the operation of the horizontal position adjustment unit 16 in real time based on the conditions of chemical solution splashing.

In an optional embodiment, the apparatus further comprises at least two height adjustment units (not shown). The height adjustment units are directly disposed on the support base 15. Each horizontal position adjustment unit 16 is mounted on a corresponding height adjustment unit.

Further, the height adjustment unit comprises a vertical guide rail and a second driving module. The horizontal position adjustment unit 16 is disposed at the outlet end of the second driving module. The horizontal position adjustment unit 16 is slidably mounted on the vertical guide rail.

During process operation, based on the pressure of the chemical solution sprayed by the nozzle 14 and the directions of chemical solution splashing, the control unit first controls the operation of the height adjustment unit. The second driving module drives the horizontal position adjustment unit 16 to move up or down, thereby adjusting the height of the protection plate 111. Subsequently, the control unit controls the operation of the horizontal position adjustment unit 16. The first driving module 163 drives the protection plate 111 to move along the horizontal guide rail 161, thereby adjusting the horizontal position of the protection plate 111. The height adjustment unit and the horizontal position adjustment unit 16 are used to jointly adjust the position of the protection plate 111.

In an optional embodiment, the baffle 112 is movably mounted on the nozzle 14. Specifically, a slide rail is provided on the outer surface of the nozzle 14. Based on the conditions of chemical solution splashing, the splash-proofing device flexibly adjusts the height of the baffle 112. The baffle 112 moves along the slide rail to a preset height and is secured in place using positioning pins, thereby reducing the chemical solution sprayed onto the surface of the nozzle 14.

In other embodiments, the swing member 17 comprises a fixed rod 171 and a swing arm 172. The swing arm 172 is rotatably mounted at one end of the fixed rod 171. The nozzle 14 is mounted at one end of the swing arm 172. The swing member 17 drives the nozzle 14 to rotate around the fixed rod 171 through swinging, thereby adjusting the horizontal position of the nozzle 14. The nozzle 14 sprays the chemical solution onto the surface of the substrate at an optimal angle to remove the photoresist.

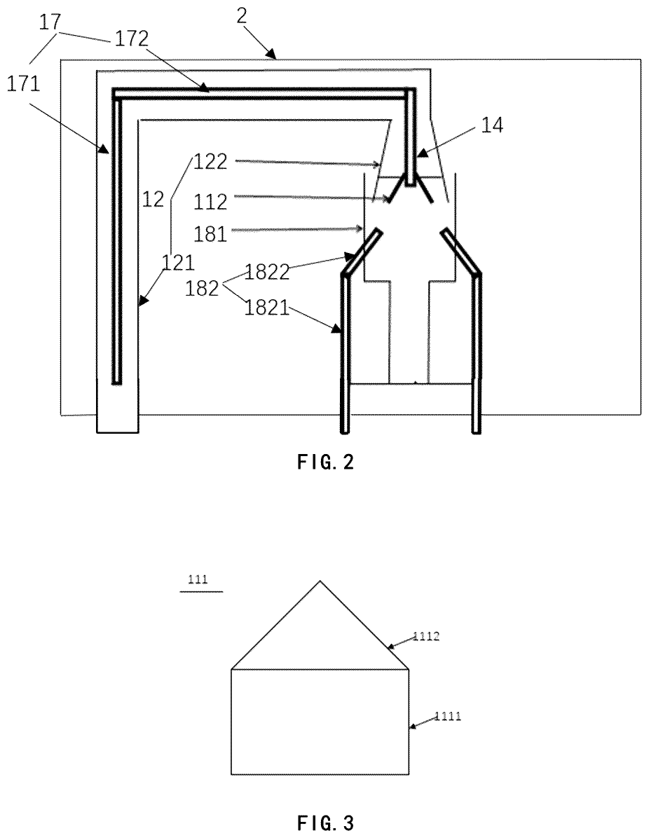

In actual processes, chemical solution splashing contaminates the baffle 112. When the accumulated chemical solution on the baffle 112 reaches a certain amount, the chemical solution may drip onto the surface of the substrate, affecting substrate processing. According to FIG. 2, in other embodiments, the apparatus further comprises a cleaning unit 18 located in the first chamber 2 at a position different from the stage 13. For example, the cleaning unit 18 is located at the rear left of the stage 13. The swing member 17 drives the nozzle 14 and the baffle 112 to rotate 90 degrees counterclockwise to a position above the cleaning unit 18. The cleaning unit 18 cleans the baffle 112. Compared to FIG. 1, FIG. 2 adds the cleaning unit 18. FIG. 1 shows a first-perspective schematic structural view of the splash-proofing device, and FIG. 2 shows a second-perspective schematic structural view of the splash-proofing device. Optionally, the relative position of the cleaning unit 18 to the stage 13 is not limited thereto. Based on the size of the space in the first chamber 2, the cleaning unit 18 is disposed at a certain angle offset from the stage 13. The swing member 17 drives the nozzle 14 and the baffle 112 to rotate through a corresponding angle to a position above the cleaning unit 18.

Exemplarily, the cleaning unit 18 comprises a recovery tank 181 and a flushing unit 182. The swing arm 172 and the nozzle 14 rotate through a preset angle relative to the fixed rod 171 to a position above the cleaning unit 18. The flushing unit 182 flushes the baffle 112, and the recovery tank 181 collects the solution after the baffle is cleaned.

Further, the flushing unit 182 comprises an inlet conduit 1821 and a spray head 1822. The spray head 1822 is rotatably disposed at the outlet end of the inlet conduit 1821. De-ionized water (DIW) is supplied from an external source through the inlet conduit 1821. The spray head 1822 periodically flushes the baffle 112 to keep the baffle 112 clean.

Tests show that atomization quality varies at different spray pressures of the chemical solution. The atomized chemical solution droplets are of different sizes. The higher the pressure, the smaller the diameter of the droplets. A greater exhaust pressure is therefore required to prevent the atomized mist from dispersing. Preferably, the nozzle 14 sprays the chemical solution at a pressure within the range of 100-1000 psi, and the vacuum pump operates at a pressure within the range of 50-500 Pa to draw the atomized chemical solution out of the first chamber 2 and prevent the first chamber 2 from being contaminated by the dispersion.

### Embodiment 2

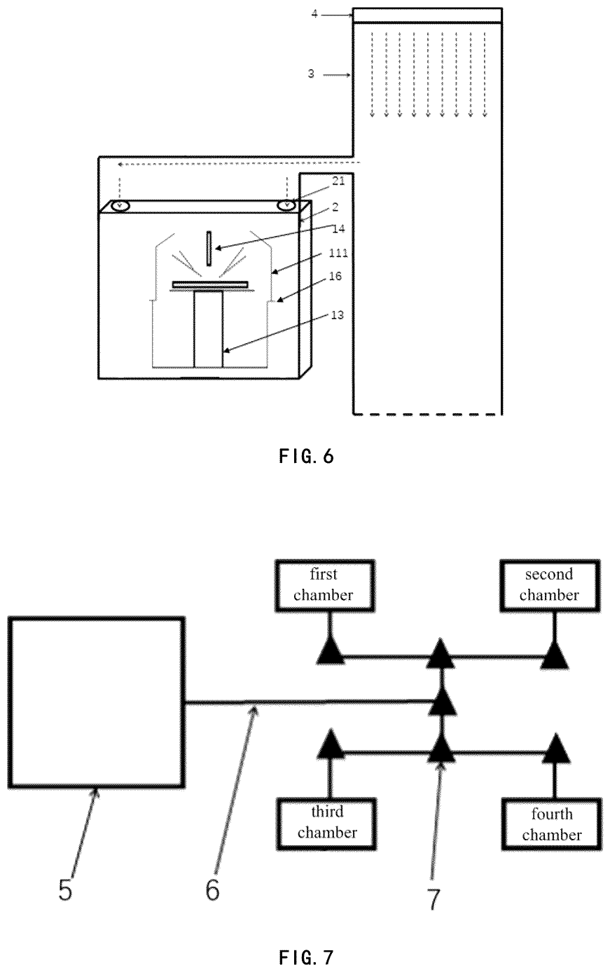

As shown in FIGS. 5 to 6, this embodiment provides a photoresist stripping apparatus comprising a first chamber 2, a filtration unit (not shown), and the splash-proofing device 1 of Embodiment 1. For simplicity, not all components of the splash-proofing device are shown in FIGS. 5 to 6. The splash-proofing device is arranged inside the first chamber 2. A plurality of vent holes 21 are provided on the top of the first chamber 2, and the vent holes 21 are in communication with the filtration unit for introducing filtered gas into the interior of the first chamber 2.

Further, the filtration unit comprises a second chamber 3 and a filter 4. The filter 4 is mounted on the top of the second chamber 3 for filtering external gas. An inlet passage is provided between the second chamber 3 and the top of the first chamber 2.

The filter 4 in this embodiment includes a filter screen and a frame surrounding the filter screen.

### Embodiment 3

As shown in FIG. 7, this embodiment provides a chemical solution delivery device applied on the photoresist stripping apparatus of Embodiment 2. The chemical solution delivery device comprises a chemical solution supply unit 5, delivery pipes 6, and valves 7. The chemical-solution supply unit 5 delivers a chemical solution through the delivery pipes 6 to the nozzles 14 in different chambers (as shown in FIG. 1). The chambers here are the first chamber 2 shown in FIGS. 1 to 2 and 5 to 6.

For different delivery paths, the numbers of the valves 7 are the same, and the lengths of the delivery pipes 6 are identical. Because the lengths of the delivery pipes 6 leading to each chamber are identical and the numbers of the valves 7 are the same, the thermal exchange between the chemical solution and the delivery pipes 6 is identical for each chamber. Consequently, the temperature reduction in each chamber is the same, ensuring that the chemical solution reaches each chamber at the same temperature. By maintaining a stable chemical solution temperature, the flowability of the chemical solution is ensured, and the impact of splashing is mitigated.

The basic concepts have been described above. Obviously, for those in the art, the above invention disclosure is merely exemplary and does not constitute a limitation to the present application. Although not explicitly stated here, those in the art may make various modifications, improvements, and corrections to the present application. Such modifications, improvements, and corrections are suggested in the present application, so such modifications, improvements, and corrections still belong to the spirit and scope of the exemplary embodiments of the present application.

Besides this, specific words are used in the present application to describe the embodiments of the present application. For example, “an embodiment,” “one embodiment,” and/or “some embodiments” refer to a certain feature, structure, or characteristic related to at least one embodiment of the present application. Therefore, it should be emphasized and noted that the “one embodiment,” “an embodiment,” or “one alternative embodiment” mentioned twice or multiple times in different positions in this specification does not necessarily refer to the same embodiment. In addition, some features, structures, or characteristics in one or more embodiments of the present application can be properly combined.

Similarly, it should be noted that in order to simplify the disclosure of the present application and facilitate understanding of one or more invention embodiments, the description of the embodiments of the present application sometimes merges a plurality of features into one embodiment, drawing, or description thereof. However, this disclosure method does not mean that the object of the present application requires more features than those mentioned in the claims. In fact, the features of embodiments are fewer than all the features of a single embodiment disclosed above.

In some embodiments, numbers describing quantities of components or properties are used. It should be understood that, in some examples, such numbers used for describing the embodiments are modified by modifiers “about,” “approximately,” or “substantially.” Unless otherwise indicated, “about,” “approximately,” or “substantially” means that the stated numbers are allowed to vary by ±20%. Correspondingly, in some embodiments, the numerical parameters used in the specification and the claims are approximations, and the approximations can vary according to the characteristics required by individual embodiments. In some embodiments, the numerical parameters should take into account specified significant digits, and the standard rounding method should be adopted. Although the numerical ranges and parameters used for confirming the breadth of the scope thereof are approximations in some embodiments of the present application, in specific embodiments, the setting of such numerical values should be as precise as practicable within the range of feasibility.

1. A splash-proofing device for a photoresist stripping process, disposed in a chamber, comprising a blocking assembly, an exhaust assembly, a stage, and a nozzle;
the stage being used to support a substrate, and the nozzle being disposed above the stage at a preset height;
the blocking assembly including at least one protection plate disposed at the periphery of the substrate for preventing chemical solution sprayed onto the substrate from splashing into the chamber;
the exhaust assembly comprising an exhaust duct and an exhaust hood in communication with each other, the exhaust hood being disposed at the periphery of the nozzle, an exhaust port of the exhaust hood being disposed above the substrate, and the exhaust assembly being used to draw splashed atomized chemical solution out of the chamber.

2. The splash-proofing device for a photoresist stripping process according to claim 1, wherein the blocking assembly further comprises a baffle, and the baffle is movably tilted at a preset angle on the nozzle for preventing the chemical solution sprayed onto the substrate from splashing into the chamber.

3. The splash-proofing device for a photoresist stripping process according to claim 2, wherein the preset angle is an acute angle.

4. The splash-proofing device for a photoresist stripping process according to claim 1, further comprising a support base, the protection plate being movably mounted on the support base.

5. The splash-proofing device for a photoresist stripping process according to claim 4, wherein the protection plate is of a hollow frustum structure.

6. The splash-proofing device for a photoresist stripping process according to claim 4, further comprising at least two horizontal position adjustment units and at least two protection plates, the horizontal position adjustment units being disposed on the support base, each protection plate being movably mounted on the corresponding horizontal position adjustment unit, and each horizontal position adjustment unit being used to drive the corresponding protection plate toward or away from the center position of the substrate.

7. The splash-proofing device for a photoresist stripping process according to claim 6, wherein the number of horizontal position adjustment units is four, the number of protection plates is four, and the four protection plates are respectively disposed in four cardinal directions around the stage.

8. The splash-proofing device for a photoresist stripping process according to claim 6, comprising two protection plates, the protection plates being of a curved-surface structure;
wherein the diameter of one protection plate on one side is greater than the diameter of the protection plate on the other side, and after the two protection plates on both sides are moved to preset positions toward the center position of the substrate, the two protection plates are in a closed state.

9. The splash-proofing device for a photoresist stripping process according to claim 6, wherein each horizontal position adjustment unit comprises a horizontal guide rail and a first driving module, and each protection plate is disposed at the outlet end of the corresponding first driving module of the horizontal position adjustment unit and is slidably mounted on the horizontal guide rail.

10. The splash-proofing device for a photoresist stripping process according to claim 6, further comprising at least two height adjustment units, the height adjustment units being directly disposed on the support base, and each horizontal position adjustment unit being mounted on the corresponding height adjustment unit;
the height adjustment unit comprising a vertical guide rail and a second driving module, and the horizontal position adjustment unit being disposed at the outlet end of the second driving module and being slidably mounted on the vertical guide rail.

11. The splash-proofing device for a photoresist stripping process according to claim 2, further comprising an swing member and a cleaning unit, the swing member including a fixed rod and a swing arm rotatably mounted on one end of the fixed rod, the nozzle being mounted on one end of the swing arm, and the swing arm being used to drive the nozzle to rotate to a position above the cleaning unit;
the cleaning unit including a recovery tank and a flushing unit, the flushing unit being used to flush the baffle, and the recovery tank being used to collect the chemical solution after the baffle is cleaned.

12. The splash-proofing device for a photoresist stripping process according to claim 11, wherein the flushing unit comprises an inlet conduit and a spray head, and the spray head is rotatably disposed at the outlet end of the inlet conduit.

13. The splash-proofing device for a photoresist stripping process according to claim 1, wherein the exhaust duct is connected to an external vacuum pump, and the nozzle sprays the chemical solution at a pressure within the range of 100-1000 psi.

14. A photoresist stripping apparatus, comprising a first chamber, a filtration unit, and the splash-proofing device according to claim 1, with the splash-proofing device being disposed in the first chamber and the filtration unit being disposed outside the first chamber;
the top of the first chamber being provided with vent holes in communication with the filtration unit for introducing filtered gas.

15. The photoresist stripping apparatus according to claim 14, wherein the filtration unit comprises a second chamber and a filter, an inlet passage is provided between the second chamber and the top of the first chamber, and the filter is mounted on the top of the second chamber for filtering external gas.

16. A chemical solution delivery device applied on the photoresist stripping apparatus according to claim 14, comprising a chemical solution supply unit, delivery pipes, and valves, wherein the chemical solution supply unit delivers the chemical solution via the delivery pipes to nozzles in different chambers, and for different delivery paths, the numbers of the valves are the same, and the lengths of the delivery pipes are identical.
